(19) United States
(12) Patent Application Publication
(10) Pub. No.: US 2024/0317060 A1
(43) Pub. Date: Sep. 26, 2024

(54) Method and Apparatus for Identifying a Malfunction of Contactors of a DC Voltage Charging Connection for an Electric Vehicle

(71) Applicant: Vitesco Technologies GmbH, Regensburg (DE)

(72) Inventor: Robert Hoffmann, Ruhstorf/Rott (DE)

(73) Assignee: Vitesco Technologies GmbH, Regensburg (DE)

(21) Appl. No.: 18/580,523

(22) PCT Filed: Jul. 13, 2022
(86) PCT No.: PCT/EP2022/069572

§ 371 Date: Jan. 18, 2024

(30) Foreign Application Priority Data
Jul. 22, 2021 (DE) 10 2021 119 037.1

(51) Int. Cl. B60L 3/00; B60L 3/12; B60L 53/14; G01R 31/00; G01R 31/327; H01H 47/00

(52) U.S. Cl. CPC B60L 3/0046; B60L 3/12; B60L 53/14; G01R 31/006; G01R 31/3275; H01H 47/002

(57) ABSTRACT

Various embodiments include methods for identifying a malfunction of a DC voltage charging connection in an electric vehicle. An example includes: driving two contactors into an open or closed state without applying a charging voltage; applying an internal reference DC voltage of the electric vehicle between both contactors, including applying a positive pole of the reference DC voltage at the first contactor and a negative pole at the second; measuring a first voltage potential between the contactors on a respective output side; measuring a second voltage potential between the contactors on a respective input side of the contactors; and identifying a malfunction of the two contactors based at least in part on the first voltage potential and the second voltage potential.

### CROSS-REFERENCE TO RELATED APPLICATIONS

This application is a U.S. National Stage Application of International Application No. PCT/EP2022/069572 filed Jul. 13, 2022, which designates the United States of America, and claims priority to DE Application No. 10 2021 119 037.1 filed Jul. 22, 2021, the contents of which are hereby incorporated by reference in their entirety.

### TECHNICAL FIELD

The present disclosure relates to electrical connections. Various embodiments of the teachings herein include methods and/or apparatus for identifying a malfunction of two contactors of a DC voltage charging connection for an electric vehicle.

### BACKGROUND

Electric vehicles typically include charging connections for connecting to DC charging stations (DC voltage charging stations). The vehicle part of the charging connection is in this case usually protected by a cover that is comparable to a gasoline or fuel tank cap. Contactors are used as disconnecting elements between vehicle charging connection and vehicle-internal power distribution. These contactors are hereinafter termed DC charging contactors or generally contactors.

For technical safety, the uncontrolled application of voltage at the charging connection must be prevented in the event of low-resistance failure of the disconnecting elements (the DC charging contactors). In certain circumstances, contactors can become stuck in the closed state in spite of an open command, for example due to mechanical blocking or welding of the switching contacts. This fault state must be reliably detected to meet safety requirements.

Diagnostic methods for the switching state of a contactor typically monitor the voltage at both connection sides of the contactor and draw a conclusion about the switching capability of the contactor by means of the comparison of the voltage values before and after a switching command. These methods sometimes fail to provide a reliable distinction between “fault” and “no fault”. The cause for this weakness is the multiplicity of disruptive influences during the operation of an electric vehicle.

The voltage measurement may be influenced by load conditions of the drives or the battery, the operating modes (e.g. recuperation mode, active/passive discharge of the HV lines following the operation of the vehicle), connected auxiliary consumers (heater, pumps, etc.). Furthermore, there is the possibility that, owing to the vehicle architecture, a voltage measurement cannot be carried out beyond the contactors prior to the closing of the contactors, because the conductive connection to the reference potential is absent. In order to avoid destruction of the contactor, both connection sides of the contactor must usually be precharged to approximately the same voltage prior to the switching operation. Therefore it is possible that only a little time (a few 10 ms) remains for carrying out the diagnosis so as not to delay the start of the vehicle unnecessarily.

Methods for detecting contacts of power contactors, which are welded or have become stuck, by means of current and voltage measurement are known from DE 10 2011 054461 A1 and DE 10 2011 077 363 A1. Furthermore, contactors are available that have what are known as auxiliary contacts for monitoring the switching state of the load contact. However, the monitoring by means of auxiliary contacts necessitates additional wiring and analysis and hides additional sources of faults. In addition, contactors with auxiliary contacts are clearly more expensive than contactors without auxiliary contacts.

### SUMMARY

The teachings of the present disclosure include methods and/or apparatus for identifying a malfunction of two contactors of a DC voltage charging connection for an electric vehicle, which exclude an endangerment of people and simplify diagnosis. For example, some embodiments include a method for identifying a malfunction of two contactors (5, 6) of a DC voltage charging connection (7) for an electric vehicle, it being possible to apply a charging voltage with a positive and negative pole between both contactors (5, 6), a first contactor (5) being arranged in the positive pole and a second contactor (6) being arranged in the negative pole, characterized by: driving one of the two contactors (5, 6) in order to move it into an open or closed state and driving the other of the two contactors (5, 6) in order to move it into an open or closed state, wherein the charging voltage is not applied; applying an internal reference DC voltage (U1) of the electric vehicle between both contactors (5, 6), wherein a positive pole of the reference DC voltage is applied at the first contactor (5) and a negative pole of the reference DC voltage (U1) is applied at the second contactor (6); measuring a first voltage potential (U1) between both contactors (5, 6) on an output side of the contactors (5, 6); measuring a second voltage potential (U2) between both contactors (5, 6) on an input side of the contactors (5, 6); and identifying the malfunction of the two contactors (5, 6) on the basis of the measured voltage potentials (U1, U2).

In some embodiments, a state A is set up, in which both contactors (5, 6) are driven in order to move them into the open state; wherein it is identified that there is no malfunction if the first voltage potential (U1) essentially corresponds to the reference DC voltage and the second voltage potential (U2) is essentially zero; and/or wherein it is identified that both contactors (5, 6) are blocked in the closed state if both the first and the second voltage potential (U1, U2) essentially correspond to the reference DC voltage.

In some embodiments, a state B is set up, in which the first contactor (5) is driven in order to move it into the open state and the second contactor (6) is driven in order to move it into the closed state; wherein it is identified that there is no malfunction if the first voltage potential (U1) essentially corresponds to the reference DC voltage and the second voltage potential (U2) is essentially zero; and/or wherein it is identified that the first contactor (5) is blocked in the closed state and the second contactor (6) is not blocked in the open state if both the first and the second voltage potential (U1, U2) essentially correspond to the reference DC voltage.

In some embodiments, a state C is set up, in which both contactors (5, 6) are driven in order to move them into the closed state; wherein it is identified that the first contactor (5) or the second contactor (6) is blocked in the open state if the first voltage potential (U1) essentially corresponds to the reference DC voltage and the second voltage potential (U2) is essentially zero; and/or wherein it is identified that there is no malfunction if both the first and the second voltage potential (U1, U2) essentially correspond to the reference DC voltage.

In some embodiments, a state D is set up, in which the first contactor (5) is driven in order to move it into the closed state and the second contactor (6) is driven in order to move it into the open state; wherein it is identified that the first contactor (5) is not blocked in the open state and the second contactor (6) is blocked in the closed state if both the first and the second voltage potential (U1, U2) essentially correspond to the reference DC voltage; and/or wherein it is identified that there is no malfunction if the first voltage potential (U1) essentially corresponds to the reference DC voltage and the second voltage potential (U2) is essentially zero.

In some embodiments, the states are set up in the sequence A, B, C, D, A.

In some embodiments, the electric vehicle has a cover that is to be opened for access to a charging connection (7) when the charging voltage is to be applied; wherein the cover is closed when the method is carried out.

In some embodiments, the method is carried out during a journey of the electric vehicle.

As another example, some embodiments include an apparatus for identifying a malfunction of two contactors (5, 6) of a DC voltage charging connection (7) for an electric vehicle, wherein it is possible to apply a charging voltage with a positive and negative pole between both contactors (5, 6), wherein a first contactor (5) is arranged in the positive pole and a second contactor (6) is arranged in the negative pole; wherein the device is configured for: driving one of the two contactors (5, 6) in order to move it into an open or closed state, and driving the other of the two contactors (5, 6) in order to move it into an open or closed state, wherein the charging voltage is not applied; applying an internal reference DC voltage of the electric vehicle between both contactors (5, 6), wherein a positive pole of the reference DC voltage is applied at the first contactor (5) and a negative pole of the reference DC voltage is applied at the second contactor (6); measuring a first voltage potential (U1) between both contactors (5, 6) on an output side of the contactors (5, 6); measuring a second voltage potential (U2) between both contactors (5, 6) on an input side of the contactors (5, 6); and identifying the malfunction of the two contactors (5, 6) on the basis of the measured voltage potentials (U1, U2).

In some embodiments, the apparatus is attached in the electric vehicle and configured to carry out one or more of the methods described herein during a journey of the electric vehicle.

### BRIEF DESCRIPTION OF THE DRAWINGS

FIG. 1 shows an equivalent circuit diagram of a circuit for carrying out an example method incorporating teachings of the present disclosure; and

FIG. 2 shows capacitances present in the equivalent circuit diagram of FIG. 1.

### DETAILED DESCRIPTION

Some examples of the teachings herein include a method for identifying a malfunction of two contactors of a DC voltage charging connection for an electric vehicle, it being possible to apply a charging voltage with a positive and negative pole between both contactors, a first contactor being arranged in the positive pole and a second contactor being arranged in the negative pole. The method may include: driving one of the two contactors in order to move it into an open or closed state, and driving the other of the two contactors in order to move it into an open or closed state, the charging voltage not being applied; applying an internal reference DC voltage (for example a battery voltage of the electric vehicle) of the electric vehicle between both contactors, wherein a positive pole of the reference DC voltage is applied at the first contactor and a negative pole of the reference DC voltage is applied at the second contactor; measuring a first voltage potential between both contactors on an output: side of the contactors; measuring a second voltage potential between both contactors on an input side of the contactors; and identifying the malfunction of the two contactors on the basis of the measured voltage potentials.

In some embodiments, a state A is set up, in which both contactors are driven in order to move them into the open state. It is identified that there is no malfunction if the first voltage potential essentially corresponds to the reference DC voltage and the second voltage potential is essentially zero; and/or it is identified that both contactors are blocked in the closed state if both the first and the second voltage potential essentially correspond to the reference DC voltage.

In some embodiments, a state B is set up, in which the first contactor is driven in order to move it into the open state and the second contactor is driven in order to move it into the closed state. It is identified that there is no malfunction if the first voltage potential essentially corresponds to the reference DC voltage and the second voltage potential is essentially zero; and/or it is identified that the first contactor is blocked in the closed state and the second contactor is not blocked in the open state if both the first and the second voltage potential essentially correspond to the reference DC voltage.

In some embodiments, a state C is set up, in which the first contactor is driven in order to move it into the closed state and the second contactor is driven in order to move it into the closed state. It is identified that the first contactor or the second contactor is blocked in the open state if the first voltage potential essentially corresponds to the reference DC voltage and the second voltage potential is essentially zero; and/or it is identified that there is no malfunction if both the first and the second voltage potential essentially correspond to the reference DC voltage.

In some embodiments, a state D is set up, in which the first contactor is driven in order to move it into the closed state and the second contactor is driven in order to move it into the open state. It is identified that the first contactor is not blocked in the open state and the second contactor is blocked in the closed state if both the first and the second voltage potential essentially correspond to the reference DC voltage; and/or it is identified that there is no malfunction if the first voltage potential essentially corresponds to the reference DC voltage and the second voltage potential is essentially zero.

In some embodiments, the states are set up in the sequence A, B, C, D, A.

In some embodiments, the electric vehicle has a cover that is to be opened for access to a charging connection when the charging voltage is to be applied; wherein the cover is closed when the previously described method is carried out.

In some embodiments, the method is carried out during a journey of the electric vehicle.

Some examples include an apparatus for identifying a malfunction of two contactors of a DC voltage charging connection for an electric vehicle, wherein it is possible to apply a charging voltage with a positive and negative pole between both contactors, wherein a first contactor is arranged in the positive pole and a second contactor is arranged in the negative pole. The apparatus is configured for driving one of the two contactors in order to move it into an open or closed state, and driving the other of the two contactors in order to move it into an open or closed state, wherein the charging voltage is not applied; applying an internal reference DC voltage (for example a battery voltage of the electric vehicle) of the electric vehicle between both contactors, wherein a positive pole of the reference DC voltage is applied at the first contactor and a negative pole of the reference DC voltage is applied at the second contactor; measuring a first voltage potential between both contactors on an output t side of the contactors; measuring a second voltage potential between both contactors on an input side of the contactors; and identifying the malfunction of the two contactors on the basis of the measured voltage potentials.

In some embodiments, the apparatus is attached in the electric vehicle and configured to carry out one or more of the described methods during a journey of the electric vehicle.

The contactor diagnosis takes place using a plurality of voltage measurements at various measurement locations on both sides of the contactor power contact and at various times (before and after a switching command). The vehicle architecture enables switching operations of the DC charging contactors for the purpose of diagnosing the charging contactors. These partial switching operations can be carried out at a time when the charging cover is closed and therefore an endangerment of people is excluded. No disruption of the voltage signal can occur here at the charging-side connection as a result. These very small capacitances may also only store a little energy.

In the context of the present disclosure, the term that a voltage potential “essentially corresponds to the reference DC voltage” may mean that a difference between the voltage potential and the reference DC voltage is smaller than a certain tolerance, for example a certain percentage of the reference voltage, for example smaller than 10%. In the context of the present patent application, the term that a voltage potential “is essentially zero” may mean that the voltage potential is smaller than a certain tolerance, for example a certain percentage of the reference voltage, for example smaller than 10%.

In the context of the present disclosure, the term “input side of the contactors” relates to the side of the contactors on which the charging voltage is applied and the term “output side of the contactors” relates accordingly to the opposite side of the contactors thereto.

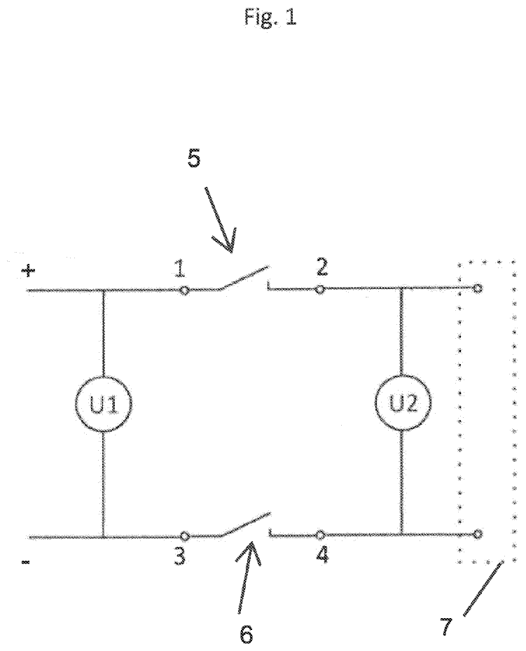

FIG. 1 shows an equivalent circuit diagram of a circuit for carrying out an example method incorporating teachings of the present disclosure. The method identifies a malfunction of two contactors 5, 6 of a DC voltage charging connection 7 for an electric vehicle, it being possible to apply a charging voltage with a positive and negative pole between both contactors 5, 6, a first contactor 5 being arranged in the positive pole and a second contactor 6 being arranged in the negative pole. The first contactor 5 is located in this case at connections 1, 2 in the positive line and the second contactor 6 is located at connections 3, 4 in the negative line.

The method includes driving one of the two contactors 5, 6 in order to move it into an open or closed state and for driving the other of the two contactors 5, 6 in order to move it into an open or closed state, wherein the charging voltage is not applied. The method includes applying an internal reference DC voltage (for example a battery voltage) U1 of the electric vehicle between both contactors 5, 6, wherein a positive pole of the reference DC voltage U1 is applied at the first contactor 5 and a negative pole of the reference DC voltage is applied at the second contactor 6. The method has a step for measuring a first voltage potential U1 between both contactors 5, 6 on an output side of the contactors 5, 6 and for measuring a second voltage potential U2 between both contactors 5, 6 on an input side of the contactors 5, 6. The method includes identifying the malfunction of both contactors 5, 6 on the basis of the measured voltage potentials U1, U2.

Initially, a state A is set up, in which both contactors 5, 6 are driven in order to move them into the open state. It is identified that there is no malfunction if the first voltage potential U1 essentially corresponds to the reference DC voltage and the second voltage potential U2 is essentially zero. In some embodiments, it is identified that both contactors 5, 6 are blocked in the closed state if both the first and the second voltage potential U1, U2 essentially correspond to the reference DC voltage.

Then, a state B is set up, in which the first contactor 5 is driven in order to move it into the open state and the second contactor 6 is driven in order to move it into the closed state. It is identified that there is no malfunction if the first voltage potential U1 essentially corresponds to the reference DC voltage and the second voltage potential U2 is essentially zero. In some embodiments, it is identified that the first contactor 5 is blocked in the closed state and the second contactor 6 is not blocked in the open state if both the first and the second voltage potential U1, U2 essentially correspond to the reference DC voltage.

If, in the state A, the second voltage potential U2 of essentially zero is measured, the transition to state B takes place, i.e. the second contactor 6 is closed. If the second voltage potential U2 alone increases due to the closing of the second contactor 6, the first contactor 5 is blocked or welded in the closed state, and it is not blocked in the open state.

Then, a state C is set up, in which the first contactor 5 is driven in order to move it into the closed state and the second contactor 6 is driven in order to move it into the closed state. It is identified that the first contactor 5 or the second contactor 6 is blocked in the open state if the first voltage potential U1 essentially corresponds to the reference DC voltage and the second voltage potential U2 is essentially zero. In some embodiments, it is identified that there is no malfunction if both the first and the second voltage potential U1, U2 essentially correspond to the reference DC voltage.

If in state B, the second voltage potential U2 of essentially zero is measured, the transition to state C takes place, the first contactor 5 is closed and the second voltage potential U2 must then increase to the value of the first voltage potential U1, otherwise one of the two contactors 5, 6 is blocked in the open state.

Then, a state D is set up, in which the first contactor 5 is driven in order to move it into the closed state and the second contactor 6 is driven in order to move it into the open state. It is identified that the first contactor 5 is not blocked in the open state and the second contactor 6 is blocked in the closed state if both the first and the second voltage potential U1, U2 essentially correspond to the reference DC voltage. In some embodiments, it is identified that there is no malfunction if the first voltage potential U1 essentially corresponds to the reference DC voltage and the second voltage potential U2 is essentially zero.

If the second voltage potential U2 is increased, the first contactor 5 is opened. The second voltage potential U2 must then decrease again. If not, the second contactor 6 is blocked in the closed state and the first contactor 5 is not blocked in the open state.

Finally, the first contactor 5 is opened again, i.e. the state A is set up again. In some embodiments, the states are set up in this sequence A, B, C, D, A.

After the completion of the test switchings, no dangerous energy remains in the area of the charging connection 7, as on the one hand the capacitances in the area are very small and on the other hand the voltage divider of the measurement at the second contactor 6 is used as passive discharge circuit.

In some embodiments, the electric vehicle has a cover that is to be opened for access to a charging connection 7 when the charging voltage is to be applied. The cover is closed when the method is carried out as described claims. In this manner, the method can be carried out outside of the charging times of the electric vehicle. It is also possible to carry out the method during a journey of the electric vehicle. Thus, a possibility of contact by people can be excluded.

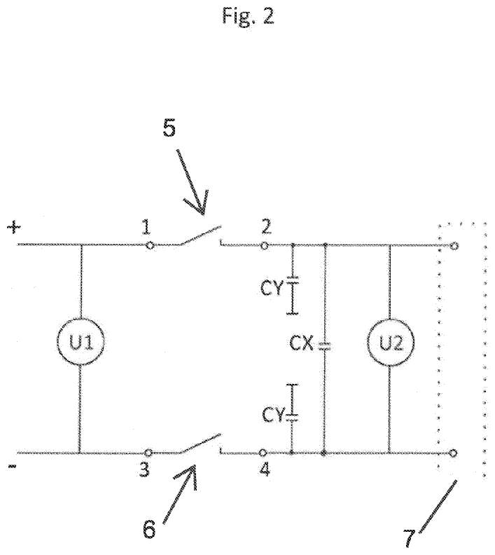

FIG. 2 shows capacitances present in the equivalent circuit diagram of FIG. 1. A capacitance between the high voltage potentials is labeled CX and a capacitance between one high voltage potential and the vehicle ground is labeled CY. There is only very little CX and CY capacitance between the contactors 5, 6 and the charging connection 7, therefore it is possible to close the contactors 5, 6 safely even without precharging the area between the charging connection 7 and the internal power distribution, i.e. high inrush currents, which could destroy the contactors 5, 6, do not occur.

What is claimed is:

1. A method for identifying a malfunction of a DC voltage charging connection in an electric vehicle with a first contactor arranged in a positive pole and a second contactor arranged in negative pole, the method comprising:
driving one of the two contactors to move it into an open or closed state and driving the other of the two contactors in order to move it into an open or closed state, without applying a charging voltage;
applying an internal reference DC voltage of the electric vehicle between both contactors, including applying a positive pole of the reference DC voltage at the first contactor and a negative pole of the reference DC voltage at the second contactor;
measuring a first voltage potential between the contactors on a respective output side of the contactors;
measuring a second voltage potential between the contactors on a respective input side of the contactors; and
identifying a malfunction of the two contactors based at least in part on the first voltage potential and the second voltage potential.

2. The method as claimed in claim 1, further comprising:
driving the connector to a state A, therein both contactors are driven into an open state;
identifying no malfunction if the first voltage potential essentially corresponds to the reference DC voltage and the second voltage potential is essentially zero; and/or
identifying both contactors as blocked in the closed state if both the first and the second voltage potential essentially correspond to the reference DC voltage.

3. The method as claimed in claim 1, further comprising:
a state B wherein the first contactor is driven into the open state and the second contactor is driven into the closed state;
identifying no malfunction if the first voltage potential essentially corresponds to the reference DC voltage and the second voltage potential is essentially zero; and/or
identifying the first contactor blocked in the closed state and the second contactor is not blocked in the open state if both the first and the second voltage potential essentially correspond to the reference DC voltage.

4. The method as claimed in claim 1, further comprising:
driving the connectors into
a state C, wherein both contactors are driven into the closed state;
identifying the first contactor or the second contactor is blocked in the open state if the first voltage potential essentially corresponds to the reference DC voltage and the second voltage potential is essentially zero; and/or
identifying no malfunction if both the first and the second voltage potential essentially correspond to the reference DC voltage.

5. The method as claimed in claim 1, further comprising:
driving the connectors into a state D, wherein the first contactor is driven into the closed state and the second contactor is driven into the open state;
identifying the first contactor are not blocked in the open state and the second contactor as blocked in the closed state if both the first and the second voltage potential essentially correspond to the reference DC voltage; and/or
identifying no malfunction if the first voltage potential essentially corresponds to the reference DC voltage and the second voltage potential is essentially zero.

6. The method as claimed in claim 1, further comprising:
driving the contactor to a state A, wherein both contactors are driven into an open state;
identifying no malfunction if the first voltage potential essentially corresponds to the reference DC voltage and the second voltage potential is essentially zero; and/or
identifying both contactors are blocked in the closed state if both the first and the second voltage potential essentially Correspond to the reference DC voltage;
driving the contactors to a state B, wherein the first contactor is driven into the open state and the second contactor is driven into the closed state;
identifying no malfunction if the first voltage potential essentially corresponds to the reference DC voltage and the second volt je potential is essentially zero; and/or
identifying the first contactor as blocked in the closed state and the second contactor as not blocked in the open state if both the first and the second voltage potential essentially correspond to the reference DC voltage,
driving the contactors to a state B, wherein the first contactor is driven into the open state and the second contactor is driven into the closed state;
identifying no malfunction if the first voltage potential essentially Corresponds to the reference DC voltage and the second voltage potential is essentially zero; and/or
identifying the first con as blocked in the closed state and e second contactor as not blocked in the open state if both the first and the second voltage potential essentially correspond to the reference DC voltage;
driving the connectors into a state D, wherein the first contactor is driven into the closed state and the second contactor is driven into the open state;
identifying the first contactor as not blocked in the open state and the second contactor as blocked in the closed state if both the first and the second voltage potential essentially correspond to the reference DC voltage; and/or
identifying no malfunction if the first voltage potential essentially corresponds to the reference DC voltage and the second voltage potential is essentially zero;
wherein the states are set up in the sequence A, B, C, D, A.

7. The method as claimed in claim 1, wherein:
the electric vehicle has a cover opened for access to the charging connection when the charging voltage is to be applied;
the cover is closed when the elements of the method are carried out.

8. The method as claimed in claim 1, further comprising executing the elements of the method during a journey of the electric vehicle.

9. An apparatus for identifying a malfunction of a DC voltage charging connection for an electric vehicle, with a first contactor arranged in a positive pole and a second contactor arranged in a negative pole of the charging connection; the apparatus comprising:
a controller to drive the two contactors into an open or closed state, without applying the charging voltage;
the controller to applying an internal reference DC voltage of the electric vehicle between both contactors, including applying a positive pole of the reference DC voltage at the first contactor and a negative pole of the reference DC voltage at the second contactor;
a meter to measuring a first voltage potential between both contactors on an output side of the contactors; and
a meter to measure a second voltage potential between both contactors on an input side of the contactors; and
wherein the controller identifies a malfunction of the two contactors based at least in part on the measured voltage potentials.

10. The apparatus as claimed in claim 9, wherein the apparatus is disposed in the electric vehicle and, during a journey of the electric vehicle:
drives one of the two contactors to move it into an open or closed state and driving the other of the two contactors in order to move it into an open of closed state, without applying a charging voltage;
applies an internal reference DC voltage of the electric vehicle between both contactors, including applying a positive pole of the reference DC voltage at the first contactor and a negative pole of the reference DC voltage at the second contactor;
measures a first voltage potential between the contactors on a respective output side of the contactors;
measures a second voltage potential between the contactors on a respective input side of the contactors; and
identifies a malfunction of the two contactors based at least in part on the first voltage potential and the second voltage potential.
